(19) United States
(12) Patent Application Publication
(10) Pub. No.: US 2011/0073344 A1
(43) Pub. Date: Mar. 31, 2011

(54) GASKET CONTAINING CARBON NANOTUBES

(75) Inventors: Yuanheng ZHANG, Bedford, MA (US); Mark HYMAN, Uxbridge, MA (US); Robert Bernard ANDERSON, III, Brighton, MA (US); Dylan LAM, Waltham, MA (US)

(73) Assignee: HYPERION CATALYSIS INTERNATIONAL, INC., Cambridge, MA (US)

(21) Appl. No.: 12/893,420

(22) Filed: Sep. 29, 2010

Related U.S. Application Data
(60) Provisional application No. 61/246,836, filed on Sep. 29, 2009.

(51) Int. Cl. H05K 5/00; C08L 27/16; C08L 63/00; B05D 5/12; C09J 163/00; B32B 27/30

(52) U.S. Cl. 174/50; 524/546; 523/468; 427/122; 156/330; 156/333; 977/742

(57) ABSTRACT

A composition for forming a gasket comprises a curable elastomer material and 0.1-20 weight % (e.g., 4-10 weight %) carbon nanotubes dispersed throughout the elastomer material. A dispensed bead of elastomer material exhibits a Slump ratio of at least 0.7. The composition provides the correct balance of rheology/dispensing characteristics, seal characteristics, and contamination profile characteristics required in form-in-place gasket applications, while simultaneously providing a conductive form-in-place gasket.

### CROSS-REFERENCE TO RELATED APPLICATIONS

This application claims the benefit of U.S. Provisional Application No. 61/246,836, filed Sep. 29, 2009, which is hereby incorporated by reference in its entirety.

### BACKGROUND

A hard disk drive (“HDD”) is a non-volatile storage device for digital data. It features one or more rotating rigid platters on a motor-driven spindle within a case. Data is encoded magnetically by read/write heads that float on a cushion of air above the platters. The case consists of a base and cover.

The cover is typically formed of a metal material, such as stainless steel or aluminum. In this regard, such metals exhibit desired structural strength, are non-magnetic metals, and are considered to be generally clean materials with respect to shedding particles within the disk drive. The cover is engaged with the disk drive base with a plurality of screws. Adequate sealing of the cover and the disk drive base is critical in order to maintain a controlled internal environment of the disk drive. To facilitate sealing, a gasket may be disposed between the cover and the disk drive base. A conventional gasket is a formed-in-place gasket (“FIPG”) that takes the form of a continuous bead of an elastomer material disposed generally about a periphery of the cover. The material may be dispensed upon the cover in a liquid form that is subsequently cured. For example, a thermoset liquid material can be dispensed onto the cover and cured prior to assembly onto the HDD. The screws are torqued so as to compress the gasket in order to achieve an adequate seal.

An FIPG must provide adequate elastomeric sealing properties to protect the HDD from environmental contamination. Additionally, the FIPG material must meet strict contamination control standards to avoid introducing contaminants to the drive.

Traditionally, non-conductive FIPG materials have been used. While conductive FIPG materials are currently available, they are undesirable and have been disqualified due to, for example, poor rheology/dispensing characteristics, too hard/inadequate seal, and poor contamination profile. What is needed is a new material to be used as a gasket, and specifically an FIPG, that provides the correct balance of properties.

### SUMMARY

Provided is a composition for forming a gasket, the composition comprising a curable elastomer material and 0.1-20 weight % carbon nanotubes dispersed throughout the elastomer material. A dispensed bead of elastomer material exhibits a Slump ratio of at least 0.7. In particular, the gasket can be an FIPG of an HDD.

Also provided is a method of forming a gasket of an electronics assembly comprising providing a cover or a base of the electronics assembly and disposing a elastomer material on the cover or base of the electronics assembly, wherein the elastomer material comprises 0.1-20 weight % carbon nanotubes dispersed throughout the elastomer material. Disposing a elastomer material on the cover or base of the electronics assembly can comprise disposing a bead of elastomer material on the cover or base of the electronics assembly, wherein the bead of elastomer material exhibits a Slump ratio of at least 0.7. Further, disposing a elastomer material on the cover or base of the electronics assembly can comprise mixing multiple compositions to form the elastomer material, wherein prior to mixing the multiple compositions to form the elastomer material, the carbon nanotubes are dispersed in one or more of the multiple compositions, and at least some of the carbon nanotubes are in the form of agglomerates. In an embodiment, at least one of the multiple compositions comprises a curing agent. Additionally provided are methods of sealing an electronics assembly.

The presently disclosed carbon nanotube-enhanced gasket provides the correct balance of rheology/dispensing characteristics, seal characteristics, and contamination profile characteristics required in FIPG applications.

### DETAILED DESCRIPTION

### Definitions

The following terms used throughout the specification have the following meanings unless otherwise indicated.

The terms “nanotube”, “nanofiber” and “fibril” are used interchangeably to refer to single walled or multiwalled carbon nanotubes. Each refers to an elongated structure having a cross section (e.g., angular fibers having edges) or a diameter (e.g., rounded) of, for example, less than 1 micron (for multiwalled nanotubes) or less than 5 nanometers (for single walled nanotubes). The term “nanotube” also includes “buckytubes” and fishbone fibrils.

“Multiwalled nanotubes” as used herein refers to carbon nanotubes which are substantially cylindrical, graphitic nanotubes of substantially constant diameter and comprise cylindrical graphitic sheets or layers whose c-axes are substantially perpendicular to the cylindrical axis, such as those described, e.g., in U.S. Pat. No. 5,171,560 to Tennent, et al. The term “multiwalled nanotubes” is meant to be interchangeable with all variations of said term, including but not limited to “multi-wall nanotubes”, “multi-walled nanotubes”, “multiwall nanotubes,” etc.

“Single walled nanotubes” as used herein refers to carbon nanotubes which are substantially cylindrical, graphitic nanotubes of substantially constant diameter and comprise a single cylindrical graphitic sheet or layer whose c-axis is substantially perpendicular to the cylindrical axis, such as those described, e.g., in U.S. Pat. No. 6,221,330 to Moy, et al. The term “single walled nanotubes” is meant to be interchangeable with all variations of said term, including but not limited to “single-wall nanotubes”, “single-walled nanotubes”, “single wall nanotubes,” etc.

“Graphenic” carbon is a form of carbon whose carbon atoms are each linked to three other carbon atoms in an essentially planar layer forming hexagonal fused rings. The layers are platelets only a few rings in diameter or they may be ribbons, many rings long but only a few rings wide.

“Graphitic” carbon consists of graphenic layers which are essentially parallel to one another and no more than 3.6 angstroms apart.

“Gasket” refers to a material installed between two surfaces to ensure a good seal (i.e., a sealant).

### Carbon Nanotubes

Carbon nanotubes exist in a variety of forms and have been prepared through the catalytic decomposition of various carbon-containing gases at metal surfaces. These include those described in U.S. Pat. No. 6,099,965 to Tennent, et al. and U.S. Pat. No. 5,569,635 to Moy, et al., both of which are hereby incorporated by reference in their entireties.

Carbon nanotubes (also known as fibrils) are vermicular carbon deposits having diameters less than 1.0 micron, for example less than 0.5 microns or less than 0.2 microns. Carbon nanotubes can be either multi walled (i.e., have more than one graphene layer more or less parallel to the nanotube axis) or single walled (i.e., have only a single graphene layer parallel to the nanotube axis). Other types of carbon nanotubes are also known, such as fishbone fibrils (e.g., wherein the graphene sheets are disposed in a herringbone pattern with respect to the nanotube axis), etc. As produced, carbon nanotubes may be in the form of discrete nanotubes, aggregates of nanotubes (i.e., dense, microscopic particulate structure comprising entangled carbon nanotubes) or a mixture of both.

In an embodiment, carbon nanotubes are made by catalytic growth from hydrocarbons or other gaseous carbon compounds, such as CO, mediated by supported or free floating catalyst particles.

Carbon nanotubes may also be formed as aggregates, which are dense microscope particulate structures of entangled carbon nanotubes and may resemble the morphology of bird nest (“BN”), cotton candy (“CC”), combed yarn (“CY”) or open net (“ON”). Aggregates are formed during the production of carbon nanotubes and the morphology of the aggregate is influenced by the choice of catalyst support. Porous supports with completely random internal texture, e.g., fumed silica or fumed alumina, grow nanotubes in all directions leading to the formation of bird nest aggregates. Combed yarn and open net aggregates are prepared using supports having one or more readily cleavable planar surfaces, e.g., an iron or iron-containing metal catalyst particle deposited on a support material having one or more readily cleavable surfaces and a surface area of at least 1 square meter per gram.

The individual carbon nanotubes in aggregates may be oriented in a particular direction (e.g., as in “CC”, “CY”, and “ON” aggregates) or may be non-oriented (i.e., randomly oriented in different directions, for example, as in “BN” aggregates). Carbon nanotube “agglomerates” are composed of carbon nanotube “aggregates”. Carbon nanotube “aggregates” retain their structure in the carbon nanotube “agglomerates”. As such, a “BN” agglomerate, for example, will contain “BN” aggregates.

“BN” structures may be prepared as disclosed in, e.g., U.S. Pat. No. 5,456,897, hereby incorporated by reference in its entirety. “BN” agglomerates are tightly packed with typical densities of greater than 0.1 g/cc, for example, 0.12 g/cc. Transmission electron microscopy (“TEM”) reveal no true orientation for carbon nanotubes formed as “BN” agglomerates. Patents describing processes and catalysts used to produce “BN” agglomerates include U.S. Pat. Nos. 5,707,916 and 5,500,200, both of which are hereby incorporated by reference in their entireties.

On the other hand, “CC”, “ON” and “CY” agglomerates have lower density, typically less than 0.1 g/cc, for example, 0.08 g/cc and their TEMs reveal a preferred orientation of the nanotubes. U.S. Pat. No. 5,456,897, hereby incorporated by reference in its entirety, describes the production of these oriented agglomerates from catalyst supported on planar supports. “CY” may also refer generically to aggregates in which the individual carbon nanotubes are oriented, with “CC” aggregates being a more specific, low density form of “CY” aggregates.

Carbon nanotubes are distinguishable from commercially available continuous carbon fibers.

For instance, the diameter of continuous carbon fibers, which is always greater than 1.0 micron and typically 5 to 7 microns, is also far larger than that of carbon nanotubes, which is usually less than 1.0 micron. Carbon nanotubes also have vastly superior strength and conductivity than carbon fibers.

Carbon nanotubes also differ physically and chemically from other forms of carbon such as standard graphite and carbon black. Standard graphite is, by definition, flat. Carbon black is an amorphous structure of irregular shape, generally characterized by the presence of both sp2 and sp3 bonding. On the other hand, carbon nanotubes have one or more layers of ordered graphitic carbon atoms disposed substantially concentrically about the cylindrical axis of the nanotube. These differences, among others, make graphite and carbon black poor predictors of carbon nanotube chemistry.

Further, the use of carbon black to increase the electrical conductivity of plastics has a number of significant drawbacks. First, the quantities of carbon black needed to achieve electrical conductivity in the polymer or plastic are relatively high, i.e., 10-60%. These relatively high loadings lead to degradation in the mechanical properties of the polymers. Specifically, low temperature impact resistance (i.e., a measure of toughness) is often compromised, especially in thermoplastics. Barrier properties also suffer. Sloughing of carbon from the surface of the materials is often experienced. This is particularly undesirable in many electronic applications. Similarly, outgassing during heating may be observed.

Taken as a whole, these drawbacks limit carbon black filled conductive polymers to the low end of the performance spectrum. For higher levels of conductivity, the designer generally resorts to metallic fillers with all their attendant shortcomings or to metal construction or even machined graphite.

The amount of carbon black that can be put into plastic can be limited by the ability to form the part for which the plastic is desired. Depending on the plastic, the carbon black, and the specific part for which the plastic is being made, it becomes impossible to form a plastic article with 20-60 weight % carbon black, even if the physical properties are not critical. In contrast, the amount of carbon nanotubes needed to achieve the correct balance of rheology/dispensing characteristics and seal characteristics in the presently disclosed elastomer materials are relatively low, i.e., less than 20 weight %. In particular, the amount of carbon nanotubes in the gasket can be, for example, 0.5 weight %, 1 weight %, or 2 weight %. While higher levels of carbon nanotubes may affect the rheology/dispensing characteristics of elastomer material containing the carbon nanotubes, in an embodiment wherein fillers such as silica and metal powders are omitted from the gasket-forming compositions, the amount of carbon nanotubes in the composition can be higher, for example, 4-10 weight %, thereby providing greater conductivity without adversely affecting the rheology/dispensing characteristics of compositions. As used herein, the term “fillers” does not include carbon nanotubes, and the term “silica” may also refer to hydrolysis products of silica.

The rheology/dispensing characteristics (e.g., slump, aspect ratio, etc.) of FIPG compositions without a thixotropic filler such as silica are unacceptable. However, acceptable rheology/dispensing characteristics can be achieved when carbon nanotubes are provided to FIPG compositions without additional thixotropic fillers, such as silica. In addition, higher levels of loading (e.g., 4-10 weight %) of carbon nanotubes can be achieved by adding carbon nanotubes to FIPG compositions without thixotropic fillers, such as silica. In embodiments, low amounts thixotropic fillers, such as silica, can be included in addition to carbon nanotubes. For example, thixotripic fillers, such as silica, can be included in amounts of less than 10 weight % or less than 5 weight %.

### Elastomer Material

The elastomer material of the presently disclosed gasket can be, for example, acrylate-based or epoxy-based. The elastomer material of the gasket can be cured (i.e., cross-linked), for example, by infrared light, microwave, ultraviolet light or thermal process. Without wishing to be bound by any theories, curing using ultraviolet light can initiate the curing mechanism in a depth that the ultraviolet light can penetrate, with bulk curing propagating to depths that the ultraviolet light cannot penetrate. The elastomer material of FIPGs is often silicon-free to meet HDD contamination requirements. Exemplary gasket elastomer materials include, for example, a one-part, ultraviolet light cured acrylate-based elastomer material (e.g., Three Bond 3089D), a one-part, thermally cured epoxy-based elastomer material (e.g., 3M™ FIPG 1280), and a two-part, thermally cured epoxy-based elastomer material (e.g., 3M™ FIPG 7109 and 7103). In an embodiment, the elastomer material can comprise silicone. In an embodiment, the elastomer material of the gasket can be moisture cured (i.e., room temperature, ambient moisture curing of, for example, a silicone elastomer material).

Regarding a two-part elastomer material, the carbon nanotubes may be dispersed in either or both of the two parts that make up the elastomer material. For example, a combined 50-50 weight % two-part elastomer material that contains 6 weight % carbon nanotubes can be made up of a part A containing 0-12 weight % carbon nanotubes and a part B containing 0-12 weight % carbon nanotubes, such that the combined elastomer material contains up to 12 weight % total carbon nanotubes. The weight percentage of carbon nanotubes in each of the parts may depend, for example, upon the ability of the carbon nanotubes to be dispersed within the part, viscosity of the part following incorporation of the carbon nanotubes, or even possible chemical reactivity of the part with the carbon nanotubes.

Among the key characteristics of gaskets, and specifically FIPGs, are rheology/dispensing characteristics, seal characteristics, and contamination profile characteristics. The presently disclosed carbon nanotube-enhanced gasket provides desirable electrical characteristics. Additionally, rheological characteristics of the presently disclosed carbon nanotube-enhanced gasket include lower viscosity, which allows for maintenance of dispensability of the conductive gasket. Further, with regard to thixotropy, the presently disclosed carbon nanotube-enhanced gasket may have greater shear thinning effect than standard materials, allowing for easier dispensing while maintaining high aspect ratio of dispensed bead (pre-cure) as well as provide anti-slump characteristics, which allows for removal of standard rheology modifiers such as silica. Removal of silica allows for additional adjustment of performance characteristics. The presently disclosed carbon nanotube-enhanced gasket has low hardness compared to alternative conductive fillers (e.g., metal powders). Furthermore, The presently disclosed carbon nanotube-enhanced gasket provides benefits in terms of cleanliness, resulting in low outgassing, low particulation, and low ionic contamination.

An exemplary two-part silica-free FIPG material includes a first part containing curing agent (“Silica-free FIPG Material Part A”), and a second part containing, for example, 45-60 weight % epoxidized rubber resin, 10-30 weight % reactive diluent, 10-20 weight % epoxy resin, and 0.5-2.5 weight % zinc catalyst (“Silica-free FIPG Material Part B”). Such silica-free FIPG material also is free of alternative conductive fillers (e.g., metal powders). In an embodiment, the carbon nanotubes are dispersed only in the Silica-free FIPG Material Part B, so as to avoid additional processing of the Silica-free FIPG Material Part A containing moisture sensitive material.

An important consideration of the presently disclosed elastomer material containing carbon nanotubes is balancing the amount of carbon nanotubes in the elastomer material. On the one hand, especially with regard to formation of an FIPG, the elastomer material must have an appropriate rheology to allow for dispensing of a gasket bead as well as maintenance of the gasket bead until curing of the FIPG. In particular, the rheology of the elastomer material should be such that the elastomer material will not slump when applied onto the substrate, otherwise the resulting gasket will not form with the proper or desired thickness, conductivity or at the proper location. Slump measures the increase in width of an uncured bead of FIPG material as a function of time after dispensing. Maintaining aspect ratio and height of an applied gasket bead is important in FIPG manufacturing. Prior to curing, the elastomer material containing carbon nanotubes can have a rheology that allows for dispensing of the bead, while preventing slumping of the bead. Rheology of the elastomer material is a function of the amount of carbon nanotubes in the elastomer material. Further, during and following curing, the bead of FIPG material should also maintain appropriate aspect ratio and height. Other important considerations of the FIPG material following curing include, for example, hardness and compression robustness, to be discussed in further detail, below. On the other hand, another factor with regard to the amount of carbon nanotubes in the elastomer material is the resulting electrical conductivity of the elastomer material, as the electrical conductivity of the elastomer material is also a function of the amount of carbon nanotubes in the elastomer material. In an embodiment, the volume resistivity of the presently disclosed conductive gasket is in the range of 10⁰-10⁸ ohm-cm.

The presently disclosed elastomer material containing carbon nanotubes dispersed throughout (in contrast to a gasket comprising an elastomer material with carbon nanotubes deposited on an outer surface of the elastomer material) can be made by any suitable means of mixing or agitation known in the art (e.g., blender, mixer, stir bar, etc.). Dispersion of the carbon nanotubes throughout the elastomer material also affects viscosity of the elastomer material.

For example, the presently disclosed elastomer material containing carbon nanotubes dispersed throughout using of a three-roll mill (or other conventional milling machine), which uses the shear force created by three horizontally positioned rolls rotating at opposite directions and different speeds relative to each other to mix, refine, disperse, or homogenize viscous materials fed into it. The milling can generate shear forces that make the carbon nanotube aggregates more uniform and smaller resulting in increased homogeneity. The milling process can be repeated until a desired consistency is obtained. The gaps on the three-roll mill can be set at, for example, less than 10 microns. The elastomer material containing carbon nanotubes can be run through the three-roll mill until it passes a particle size test of, for example, below 10 microns.

The carbon nanotubes can be dispersed using, for example, a sonicator. In particular, a probe sonicator (available from Branson Ultrasonics Corporation of Danbury, Conn.) can be used at a high enough power setting to ensure substantially uniform dispersion (e.g., 450 Watts can be used). Sonication may continue until a gel-like slurry of substantially uniformly dispersed nanotubes is obtained.

### Gasket Formation

In the FIPG manufacturing process, a gasket bead is dispensed (e.g., on the cover of a HDD) using air pressure or mixing/metering pumps and a programmable dispensing machine. A typical dispensing needle is 18-19 gauge (0.83 mm, 0.68 mm) Dispensing process parameters that influence gasket geometry include, for example, dispense rate, x-y speed, needle diameter, and height of the needle above the substrate. An advantage of the presently disclosed elastomer material containing carbon nanotubes, as compared to currently available conductive FIPG materials containing, for example, nickel or nickel-plated graphite particles, is that clogging of the dispensing needle may be avoided.

In an embodiment, properties of the elastomer materials, before curing, include a flowability of 0.24 to 2.9 grams, for example, 0.24 to 0.42 grams or 0.24 to 0.80 grams, dispensed using an EFD 1500 Dispenser from a 30 cc reservoir (syringe), through an orifice (needle tip 14 tt from EFD) having a diameter of 1.6 mm, under a pressure of 60 psi applied to the reservoir for a duration of 20 seconds. Further, the dimensional stability of a dispensed gasket can be assessed by measuring the height and width of a cured gasket bead that had been dispensed at 60 psi through a 14 tt syringe tip (1.6 mm opening) available from EFD. The syringe tip is held 9.5 mm from a substrate while the syringe slowly moved at about 5.0 mm/sec to allow the bead of material to gently fall upon the substrate. The dispensed bead is cured at 160° C. for two hours. A small length of the bead is sliced with a razor blade to obtain a cross section which is examined under a microscope to measure the bead height and width. In an embodiment, the aspect ratio, determined by dividing the bead height by the bead width, is 0.5 to 0.9 or 0.5 to 1.0

Properties of the elastomer materials, after curing, include low outgassing and low extractable ionic contamination. More particularly, in an embodiment, the elastomer materials, after curing, have a compression set of about 7% to about 25%, for example, about 7% to about 20% or about 10% to about 15% (as measured by ASTM D395B), a level of outgassing components of about 10 μg/g to about 45 μg/g (as measured by GC/Mass Spectroscopy), and a Shore A durometer hardness from about 35 to about 90, for example, from about 44 to about 68 or from about 50 to about 60 (samples with a thickness of about 6 mm tested for hardness using a Shore A durometer tester at room temperature). Further, after curing, the glass transition temperature (T_{g}) of cured specimens can be determined using a differential scanning calorimeter (DSC). In an embodiment, the T_{g}, selected as the midpoint in the transition region between the glass and rubbery temperature regions in the DSC heating scan, is −40° to −46° C.

Following dispensing of the bead, the elastomer material is cured prior to compression of the elastomer material between the surfaces to be sealed. After curing, the elastomer material containing carbon nanotubes should have a hardness that ensures a good seal. For example, the elastomer material containing carbon nanotubes can have a durometer hardness of less than 90 Shore A. In an embodiment, the elastomer material containing carbon nanotubes can have durometer hardness of not less than 35 Shore A. As would readily be understood by one skilled in the art, durometer hardness can be measured, for example, by ASTM D2240.

Without wishing to be bound by any theories, it is believed that incorporation of carbon nanotubes into the elastomer material may allow for use of gaskets having higher hardness than previously used. In particular, incorporation of carbon nanotubes into the elastomer material may result in a gasket that can be subjected to higher levels of compression without failure. Accordingly, a gasket with a higher hardness value than previously used could still provide a good seal with additional compression of the gasket, without failure.

In an embodiment, a double bead (i.e., double height) is dispensed, wherein a gasket bead is dispensed and then cured, followed by dispensing and curing of a second gasket bead atop the cured first gasket bead. Accordingly, a high profile or aspect ratio bead can be formed. In an embodiment, dispensed bead heights can range, for example, from 0.018 to 0.13 inches, while gasket thicknesses can range, from example, from 3 mils to over ¼ inches.

In an embodiment, a method of sealing an electronics assembly (e.g., a hard disk drive or a cell phone) comprises disposing a carbon nanotube-loaded elastomer sheet (e.g., a thermoset fluoroelastomer sheet) between a cover and a base of the electronics assembly and compressing the elastomer material between the cover and the disk drive base. Thermoset fluoroelastomer sheets do not require the same rheology/dispensing characteristics as FIPGs, and thus, can have higher carbon nanotube loadings. In an embodiment, a thermoset fluoroelastomer sheet can have a carbon nanotube loading of, for example, 0.1-5 weight %. The carbon nanotube-loaded elastomer sheet may be cut to appropriate size prior to disposition between the cover and the base of the electronics assembly. In an embodiment, the thermoset fluoroelastomer sheet can be molded in a fixed steel mold, and then removed, deflashed, and disposed between the cover and base of the electronics assembly. The durometer hardness of the thermoset fluoroelastomer sheet can be, for example, greater than 55 Shore A.

In an embodiment, a method of sealing an electronics assembly comprises molding a thermoplastic elastomer material on a cover of the electronics assembly and compressing the thermoplastic elastomer material between the cover and a base of the electronics assembly, wherein the thermoplastic elastomer material comprises carbon nanotubes dispersed throughout. As compared to currently available thermoplastic elastomer materials for molding on a cover of a hard disk drive, a thermoplastic elastomer material comprising carbon nanotubes dispersed throughout would provide improvements in cleanliness and hardness values for sealing.

The following examples are merely illustrative and intended to be non-limiting.

### EXAMPLES

Unless otherwise specified, durometer hardness values are measured by ASTM D2240.

### Example 1

Fluoroelastomer sheets were formed from Technoflon® P 457 peroxide curable fluoroelastomer into which had been dispersed a concentrate of 12 weight % CC FIBRIL™ nanotubes manufactured by Hyperion Catalysis International, Inc., Cambridge, Mass., in peroxide curable fluoroelastomer and minor amounts of cross-linking agents using a 27 mm extruder. The sheets were press cured for 10 minutes at 177° C. followed by post cure for 16 hours at 180° C. Properties of the formed fluoroelastomer sheets are presented in Table 1.

TABLE 1

| Sample | A | B |
|---|---|---|
| Carbon Nanotube Loading | 2.77 wt % | 3.66 wt % |
| Volume Resistivity (ohm-cm) | 1.75E+02 | 1.51E+01 |
| Surface Resistivity (ohm-sq) | 4.46E+02 | 3.97E+01 |
| Measurement voltage | 10.0 | 10.0 |
| Durometer Hardness (post-cure) | 75 Shore A | 80 Shore A |

### Example 2

A sample formulation was made by mixing 3M™ Form-In-Place Gasket 7103 Part A, 3M™ Form-In-Place Gasket 7103 Part B, and carbon nanotubes in a three-roll mill. The ratio of Part B:Part A was 1.63:1 and the sample contained 1.25 weight % carbon nanotubes. Strands of FIPG material were dispensed and tested after curing. The strands of FIPG material had a diameter of 1.35 mm following curing. The carbon nanotubes were CC FIBRIL™ nanotubes manufactured by Hyperion Catalysis International, Inc., Cambridge, Mass. 3M™ Form-In-Place Gasket 7103 Part B contains 40-70 weight % epoxidized rubber resin, 15-40 weight % epoxy resin, 10-30 weight % hydrophobic silica, 10-30 weight % hydrogenated fatty acid derivatives, and 0.5-1.5 weight % zinc stearate, while 3M™ Form-In-Place Gasket 7103 Part A contains 70-90 weight % dodecenylsuccinic anhydride and 10-30 weight % hydrophobic silica.

The volume conductivity along the length of the strand with no compression applied on the strand, with silver paint was applied on both ends of the strand, testing voltage of 1 volt (“Vr. no comp. strand”) was 7.9E+04 ohm-cm. The volume conductivity along the cross-section of the strand, which was under 20-30% compression, testing voltage of 1 volt (“Vr. low comp. cross section”) was 1.6E+08 ohm-cm. The volume conductivity along the cross-section of the strand, which was under 45-55% compression, testing voltage of 1 volt (“Vr. high comp. cross section”) was 2.3E+08 ohm-cm.

### Example 3

Sample formulations 3a-3n were made by mixing Silica-free FIPG Material Part A, Silica-free FIPG Material Part B, and carbon nanotubes in a three-roll mill. Uncured material was dispensed from a 30 cc syringe through an orifice (needle tip 14 TT from EFD) having a diameter of 1.6 mm. A pressure of 60 psi was applied to the syringe for 20 seconds and the weight of material passing through the orifice under pressure was recorded as “Flowability”.

Strands of uncured FIPG material were dispensed and tested both prior to and after curing. Two different types of carbon nanotubes were tested—CC and BN FIBRIL™ nanotubes, both manufactured by Hyperion Catalysis International, Inc., Cambridge, Mass. Properties of the sample formulations are presented in Table 2.

TABLE 2

| | Sample Number | | | | | |
|---|---|---|---|---|---|---|
| | 3a | 3b | 3c | 3d | 3e | 3f |
| Silica-free FIPG Material, Ratio of Parts B/A | 2/1 | 2/1 | 2/1 | 2/1.2 | 2/1.4 | 3/1 |
| BN FIBRIL ™ nanotubes (weight %) | — | — | — | — | — | — |
| CC FIBRIL ™ nanotubes (weight %) | 2% | 4% | 6% | 6% | 6% | 5% |
| Slump ratio | | | 1 | 1 | 1 | 1 |
| Aspect ratio | 0.56 | 0.875 | 1 | 0.91 | 0.94 | 1 |
| Hardness (Shore A) | 41 | 54 | 57 | 64 | 56 | 44 |
| Compression set | | 5.7% | | 9% | 13% | 19% |
| Compression robustness | | | | >89% | 56% | 80% |
| Flowability (grams per 20 seconds) | | | <0.05 | 0.053 | 0.1 | 0.398 |
| Vr. no comp. strand (ohm-cm) | 3.0E+01 | 9.2E+01 | | 3.0E+02 | 9.5E+00 | 5.6E+02 |
| Vr. low comp. cross section (ohm-cm) | | 7.1E+04 | | 1.8E+04 | 1.5E+04 | 1.2E+05 |
| Vr. high comp. cross section (ohm-cm) | | 1.7E+06 | | 4.3E+04 | 4.9E+04 | 1.0E+06 |

| | Sample Number | | | | | | | |
|---|---|---|---|---|---|---|---|---|
| | 3g | 3h | 3i | 3j | 3k | 3l | 3m | 3n |
| Silica-free FIPG Material, Ratio of Parts B/A | 2/1 | 2/1 | 2/1 | 2/1 | 2/1.2 | 2/1.2 | 2/1 | 2/1.2 |
| BN FIBRIL ™ nanotubes (weight %) | 4% | 6% | 8% | 10% | 8% | 10% | 6% | 6% |
| CC FIBRIL ™ nanotubes (weight %) | — | — | — | — | — | — | 2% | 2% |
| Slump ratio | <0.2 | | 1 | 1 | 1 | 1 | 1 | 1 |
| Aspect ratio | <0.2 | 0.84 | 0.97 | 1 | 0.95 | 1 | 0.97 | 1 |
| Hardness (Shore A) | | 58 | 66 | 67 | 53 | 61 | 66 | 54 |
| Compression set | | 5.0% | 22.5% | 11% | 21% | 25% | 17% | 25% |
| Compression robustness | | 79.0% | 78% | 66% | 56% | 68% | 75% | 68% |
| Flowability (grams per 20 seconds) | | | 0.277 | | 0.769 | 0.238 | 0.275 | 0.286 |
| Vr. no comp. strand (ohm-cm) | | 3.6E+02 | 2.9E+01 | 8.3E+00 | 7.0E+00 | 4.0E+00 | 1.6E+02 | 2.2E+01 |
| Vr. low comp. cross section (ohm-cm) | | 9.6E+06 | 1.4E+05 | 1.7E+04 | 6.9E+03 | 5.1E+02 | 2.6E+03 | 2.3E+03 |
| Vr. high comp. cross section (ohm-cm) | | 5.0E+07 | 2.9E+04 | 5.1E+03 | 1.6E+04 | 1.4E+03 | 1.0E+04 | 2.3E+04 |

The “Slump ratio” is (width of FIPG strand 1 minute after dispensing)/(width of FIPG strand 1 hour after dispensing). The “Aspect ratio” is (Height/Width) of FIPG strand after 3 hours, 160° C. curing process. The “Compression set” is (original height−height)/(original height). More specifically, the height of the FIPG strand (i.e., gasket) was measured (“original height”), after which the gasket was compressed to 50% compression for 16 hours at 65° C. The gasket was allowed to cool to ambient, the compression relieved, and the gasket was allowed to recover one hour before measuring the height. The “Compression robustness” is a measure of the maximum compression with no hairline cracks or other signs of degradation under 10 times magnification after an FIPG strand was kept under compression for 16 hours at 80° C.

A control sample comprised a first part containing 85-92 weight % curing agent and 8-15 weight % thixotropic filler (silica), and a second part containing 45-60 weight % epoxidized rubber resin, 10-30 weight % reactive diluent, 10-20 weight % epoxy resin, 10-20 weight % thixotropic filler (silica), and 0.5-2.5 weight % zinc catalyst. The ratio of the second part to the first part was 2:1. The control sample exhibited an aspect ratio of 0.87, a hardness of 44 Shore A, a compression set value of 6%, a compression robustness value of 66%, and a flowability of 2.844 grams per 20 seconds.

The Slump ratio of the present composition for forming a gasket is desirably at least 0.7, for example, at least 0.73. Desirable values for the compression set can be, for example, 25% or less (see, for example, sample 31) or 10% or less (see, for example, sample 3d). Further, desirable values for the compression robustness can be, for example, 50% or greater (see, for example, samples 3d and 31). Additionally, desirable values for the aspect ratio can be, for example, greater than 0.75 or greater than 0.90 (see, for example, samples 3d and 31).

Commercially available 3M™ Form-In-Place Gasket 7109 Part B contains 30-60 weight % polyester diol, 10-30 weight % hydrophobic silica, 15-30 weight % epoxidized rubber resin, 5-15 weight % epoxy resin, and 1-5 weight % zinc stearate, while 3M™ Form-In-Place Gasket 7109 Part A contains 70-90 weight % alkenyl succinic anhydride and 10-30 weight % hydrophobic silica. For comparison, a sample of 3M™ Form-In-Place Gasket 7109 with a ratio of Part B:Part A of 2:1 (i.e., a silica-filled FIPG material not containing carbon nanotubes) had a Slump ratio of 1, an Aspect ratio of 0.94, a Hardness of 45 Shore A, a Compression set of 9%, a Compression robustness of 51%, and a Flowability of 2.94 grams.

The voltage used in the conductivity tests of Example 3 was 1 volt; it is believed that if the voltage used in the conductivity tests was increased to 10-100 volts, the volume conductivity of some of the formulations would increase one to two orders of magnitude. The conductivity robustness of the samples of Example 3 show improvement over Example 2 (i.e., a silica-filled FIPG formulation containing carbon nanotubes). While both the samples of Example 3 and Example 2 lost conductivity under compression, elimination of silica from the FIPG formulations of Example 3 allowed for higher loading levels of carbon nanotubes, resulting in higher initial conductivity levels, and acceptable conductivity levels even after reduction under compression.

CC and BN FIBRIL™ nanotubes have different effects on viscosity and maintaining conductivity under compression. As the viscosities of the separate parts of a two-part silica-free FIPG Material may differ, CC and/or BN FIBRIL™ nanotubes could be utilized to create compound materials (i.e., Part A including FIBRIL™ nanotubes and/or Part B including FIBRIL™ nanotubes) with closer viscosities, which may result in better mixing when subsequently combined.

Silica-free FIPG materials containing carbon nanotubes may provide a better balance of softness and slump characteristics than silica-filled FIPG materials. Silica-free FIPG materials containing carbon nanotubes can attain nearly zero slump. Additionally, uncured samples of mixed (i.e., Part A and Part B) silica-free two-part FIPG materials containing carbon nanotubes may provide improvements in pot life as compared to FIPG materials not containing carbon nanotubes.

While various embodiments have been described, it is to be understood that variations and modifications may be resorted to as will be apparent to those skilled in the art. Such variations and modifications are to be considered within the purview and scope of the claims appended hereto. For example, the presently disclosed gasket is not intended to be limited to sealing of electronics assemblies.

What is claimed is:

1. A composition for forming a gasket, the composition comprising:
a curable elastomer material; and
about 0.1-20 weight % carbon nanotubes dispersed throughout the elastomer material;
wherein a dispensed bead of elastomer material exhibits a Slump ratio of at least 0.7.

2. The composition of claim 1, wherein the elastomer material is selected from the group consisting of an acrylate-based elastomer material and an epoxy-based elastomer material.

3. The composition of claim 1, wherein the composition contains less than 10 weight % fillers.

4. The composition of claim 3, wherein the composition does not contain silica or metal powder.

5. The composition of claim 3, wherein the composition contains less than 5 weight % silica.

6. The composition of claim 1, wherein the composition comprises 4-10 weight % carbon nanotubes dispersed throughout the elastomer material.

7. The composition of claim 1, wherein the composition has a flowability of 0.24 to 0.80 grams per 20 seconds.

8. A gasket formed from the composition of claim 1.

9. An electronics assembly comprising:
a cover;
a base; and
a gasket formed from the composition of claim 1 disposed between the cover and the base.

10. The electronics assembly of claim 9, wherein the gasket has a hardness that provides adequate sealing of the electronics assembly.

11. The electronics assembly of claim 10, wherein the gasket has a Shore A durometer hardness from about 35 to about 90.

12. A method of forming a gasket of an electronics assembly comprising:
providing a cover or a base of the electronics assembly; and
disposing an elastomer material on the cover or base of the electronics assembly;
wherein the elastomer material comprises 0.1-20 weight % carbon nanotubes dispersed throughout the elastomer material.

13. The method of claim 12, wherein disposing an elastomer material on the cover or base of the electronics assembly comprises disposing a bead of elastomer material on the cover or base of the electronics assembly, wherein the bead of elastomer material exhibits a Slump ratio of at least 0.7.

14. The method of claim 13, wherein the elastomer material has a flowability of 0.24 to 0.80 grams per 20 seconds.

15. The method of claim 13, wherein:
disposing an elastomer material on the cover or base of the electronics assembly comprises mixing multiple compositions to form the elastomer material;
prior to mixing the multiple compositions to form the elastomer material, the carbon nanotubes are dispersed in one or more of the multiple compositions; and
at least some of the carbon nanotubes are in the form of agglomerates.

16. The method of claim 15, wherein at least one of the multiple compositions comprises a curing agent.

17. The method of claim 13, wherein the elastomer material is selected from the group consisting of an acrylate-based elastomer material and an epoxy-based elastomer material, and further wherein the elastomer material contains less than 5 weight % filler material selected from the group consisting of silica, metal powder, and combinations thereof.

18. A method of sealing an electronics assembly comprising:
forming a gasket of an electronics assembly according to claim 13;
curing the elastomer material; and
compressing the elastomer material between the cover and the base.

19. The method of claim 18, wherein after curing, the elastomer material has a Shore A durometer hardness from about 35 to about 90.

20. A method of sealing an electronics assembly comprising:
forming a gasket of an electronics assembly according to claim 12, wherein disposing an elastomer material on the cover or base of the electronics assembly comprises disposing a molded thermoplastic elastomer material on the cover or base of the electronics assembly; and
compressing the elastomer material between the cover and the base.
